(19) United States
(12) Patent Application Publication
(10) Pub. No.: US 2026/0206210 A1
(43) Pub. Date: Jul. 16, 2026

(54) INCREASED ACTIVE AREA FOR SEMICONDUCTOR PILLARS

(71) Applicant: Micron Technology, Inc., Boise, ID (US)

(72) Inventors: Maryam SAYYAH, Boise, ID (US); Ashkan BEHNAM, Boise, ID (US); Vivek YADAV, Boise, ID (US)

(21) Appl. No.: 19/394,726

(22) Filed: Nov. 19, 2025

Related U.S. Application Data
(60) Provisional application No. 63/745,018, filed on Jan. 14, 2025.

(51) Int. Cl. H10B 12/00

(52) U.S. Cl. CPC H10B 12/34; H10B 12/053

(57) ABSTRACT

Implementations described herein relate to various structures, integrated assemblies, and memory devices. In some implementations, an integrated assembly includes one or more semiconductor pillars extending vertically from a substrate, the one or more semiconductor pillars including respective upper portions having a first width in a horizontal direction and the one or more semiconductor pillars including respective lower portions having a second width in the horizontal direction, where the first width is greater than the second width. The integrated assembly may further include a dielectric material extending between the one or more semiconductor pillars, where the respective upper portions extend over respective portions of the dielectric material.

### CROSS-REFERENCE TO RELATED APPLICATION

This Patent Application claims priority to U.S. Provisional Patent Application No. 63/745,018, filed on January 14, 2025, entitled “INCREASED ACTIVE AREA FOR SEMICONDUCTOR PILLARS,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to an increased active area for semiconductor pillars.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a diagrammatic view of an example memory device.

FIG. 2 is a circuit diagram of an example memory cell.

FIG. 3 is a diagrammatic view of an example structure described herein. FIG. 3 includes a top-down view of the structure and a cross-sectional view along the plane A-A’ of FIG. 3.

FIG. 4 is a flowchart of an example method of forming an integrated assembly or memory device having an increased active area for semiconductor pillars.

FIGS. 5A through 5I are diagrammatic views showing formation of the structure at example process stages of an example process of forming the structure.

FIGS. 6A and 6B are diagrammatic views showing formation of the structure at example process stages of an example process of forming the structure.

FIG. 7 is a cross-sectional diagrammatic view of an example structure described herein.

### DETAILED DESCRIPTION

Some memory device manufacturing processes, such as DRAM manufacturing processes, may include forming an array of semiconductor pillars in a semiconductor wafer by etching one or more trenches into the wafer to define the semiconductor pillars. These semiconductor pillars may have respective active areas (e.g., upper surfaces of the semiconductor pillars) configured to interface with various components of the memory device, such as cell contacts and/or digit line contacts. However, due to the aspect ratio of the semiconductor pillars after etching, potential defects such as pillar toppling, bending, and/or clogging may limit potential manufacturing steps such as forming a polysilicon liner over the semiconductor pillars to increase the active area.

Some implementations described herein enable an increased active area for semiconductor pillars. For example, a manufacturing process may include etching a set of trenches in a semiconductor wafer to define one or more semiconductor pillars. The process may further include forming a dielectric material, such as an oxide, to fill the one or more trenches. The process may include recessing the dielectric material to expose upper surfaces and upper portions of sidewalls of the semiconductor pillars. Subsequently, a polysilicon liner may be formed over the exposed portions of the semiconductor pillars. Subsequently, one or more portions of the polysilicon liner may be removed to isolate adjacent semiconductor pillars and/or expose upper surfaces of the semiconductor pillars, while retaining one or more overhangs abutting the upper sidewall portions of the semiconductor pillars. These overhangs may increase the effective active area of the semiconductor pillars.

By increasing the active area of semiconductor pillars, the manufacturing process may enhance performance and/or reliability of a memory device. For example, an increased active area may allow for more robust and reliable connections between the semiconductor pillars and contacts, such as cell contacts and/or digit line contacts, formed as part of subsequent manufacturing operations. Additionally, because of the reduced aspect ratio of the exposed portions of the semiconductor pillars during deposition of the polysilicon liner, the likelihood of manufacturing defects resulting from depositing the polysilicon liner may be reduced.

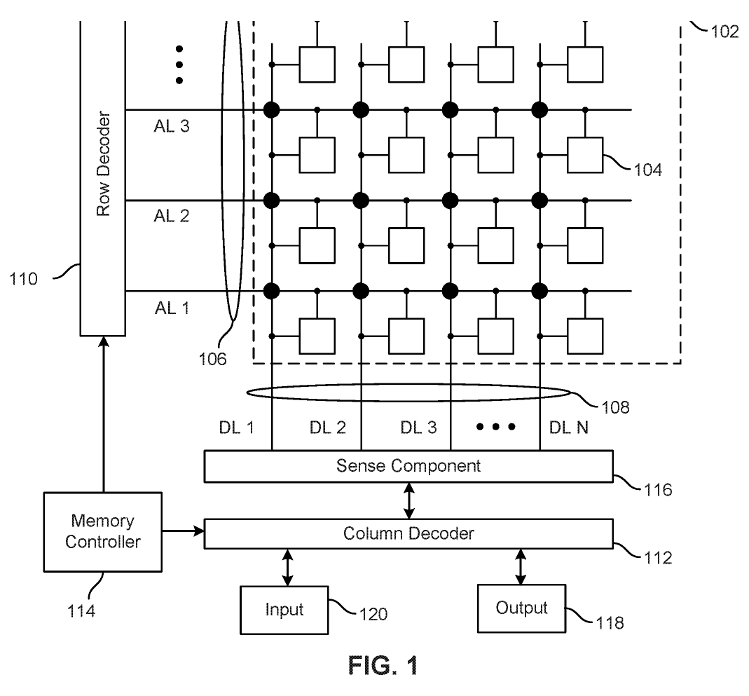

FIG. 1 is a diagrammatic view of an example memory device 100. The memory device 100 may include a memory array 102 that includes multiple memory cells 104. A memory cell 104 is programmable or configurable into a data state of multiple data states (e.g., two or more data states). For example, a memory cell 104 may be set to a particular data state at a particular time, and the memory cell 104 may be set to another data state at another time. A data state may correspond to a value stored by the memory cell 104. The value may be a binary value, such as a binary 0 or a binary 1, or may be a fractional value, such as 0.5, 1.5, or the like. A memory cell 104 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 104 by activating or selecting the appropriate access line 106 (shown as access lines AL 1 through AL M) and digit line 108 (shown as digit lines DL 1 through DL N). An access line 106 may also be referred to as a “row line” or a “word line,” and a digit line 108 may also be referred to a “column line” or a “bit line.” Activating or selecting an access line 106 or a digit line 108 may include applying a voltage to the respective line. An access line 106 and/or a digit line 108 may comprise, consist of, or consist essentially of a conductive material, such as a metal (e.g., copper, aluminum, gold, titanium, or tungsten) and/or a metal alloy, among other examples. In FIG. 1, each row of memory cells 104 is connected to a single access line 106, and each column of memory cells 104 is connected to a single digit line 108. By activating one access line 106 and one digit line 108 (e.g., applying a voltage to the access line 106 and digit line 108), a single memory cell 104 may be accessed at (e.g., is accessible via) the intersection of the access line 106 and the digit line 108. The intersection of the access line 106 and the digit line 108 may be called an “address” of a memory cell 104.

In some implementations, the logic storing device of a memory cell 104, such as a capacitor, may be electrically isolated from a corresponding digit line 108 by a selection component, such as a transistor. The access line 106 may be connected to and may control the selection component. For example, the selection component may be a transistor, and the access line 106 may be connected to the gate of the transistor. Activating the access line 106 results in an electrical connection or closed circuit between the capacitor of a memory cell 104 and a corresponding digit line 108. The digit line 108 may then be accessed (e.g., is accessible) to either read from or write to the memory cell 104.

A row decoder 110 and a column decoder 112 may control access to memory cells 104. For example, the row decoder 110 may receive a row address from a memory controller 114 and may activate the appropriate access line 106 based on the received row address. Similarly, the column decoder 112 may receive a column address from the memory controller 114 and may activate the appropriate digit line 108 based on the column address.

Upon accessing a memory cell 104, the memory cell 104 may be read (e.g., sensed) by a sense component 116 to determine the stored data state of the memory cell 104. For example, after accessing the memory cell 104, the capacitor of the memory cell 104 may discharge onto its corresponding digit line 108. Discharging the capacitor may be based on biasing, or applying a voltage, to the capacitor. The discharging may induce a change in the voltage of the digit line 108, which the sense component 116 may compare to a reference voltage (not shown) to determine the stored data state of the memory cell 104. For example, if the digit line 108 has a higher voltage than the reference voltage, then the sense component 116 may determine that the stored data state of the memory cell 104 corresponds to a first value, such as a binary 1. Conversely, if the digit line 108 has a lower voltage than the reference voltage, then the sense component 116 may determine that the stored data state of the memory cell 104 corresponds to a second value, such as a binary 0. The detected data state of the memory cell 104 may then be output (e.g., via the column decoder 112) to an output component 118 (e.g., a data buffer). A memory cell 104 may be written (e.g., set) by activating the appropriate access line 106 and digit line 108. The column decoder 112 may receive data, such as input from input component 120, to be written to one or more memory cells 104. A memory cell 104 may be written by applying a voltage across the capacitor of the memory cell 104.

The memory controller 114 may control the operation (e.g., read, write, re-write, refresh, and/or recovery) of the memory cells 104 via the row decoder 110, the column decoder 112, and/or the sense component 116. The memory controller 114 may generate row address signals and column address signals to activate the desired access line 106 and digit line 108. The memory controller 114 may also generate and control various voltages used during the operation of the memory array 102.

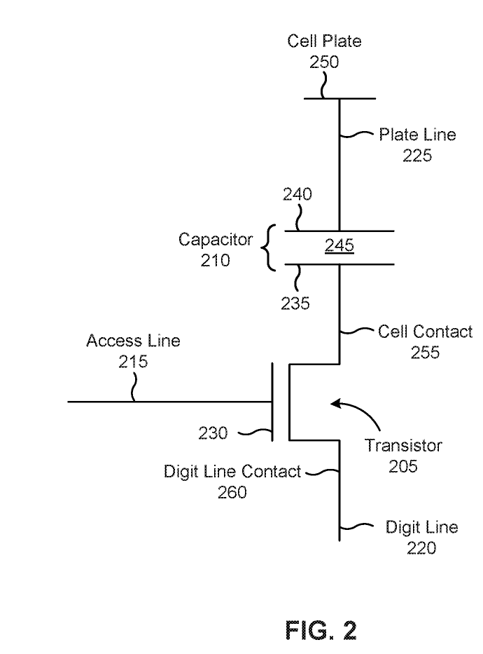

In some implementations, the memory device 100 may include one or more semiconductor pillars having respective overhangs. For example, as described in greater detail in connection to FIG. 2, a memory cell 104 may include a transistor having a cell contact and a digit line contact. The cell contact and digit line contact may act as source and/or drain terminals of the transistor, and may couple to respective semiconductor pillars using upper surfaces (e.g., active areas) of the semiconductor pillars. An overhang of a semiconductor pillar may increase the active area of the semiconductor pillar, which may allow for more robust and reliable connections between the semiconductor pillar and contacts, such as a cell contact and/or a digit line contact.

As indicated above, FIG. 1 is provided as an example. Other examples may differ from what is described with respect to FIG. 1.

FIG. 2 is a circuit diagram of an example memory cell 200. In some implementations, the memory cell 200 may be a linear dielectric memory cell or a paraelectric memory cell. Alternatively, the memory cell 200 may be a ferroelectric memory cell. As shown in FIG. 2, the memory cell 200 may include a transistor 205 (or another type of selection circuit) and a capacitor 210. The memory cell 200 may be accessed (e.g., written to, read from, and/or erased) using signals on a combination of lines that are coupled to the memory cell 200, shown as an access line 215 (sometimes called a “word line”), a digit line 220 (sometimes called a “bit line”), and, in some cases, a plate line 225.

The transistor 205 (sometimes called an access transistor) may include a gate 230. The capacitor 210 includes a bottom electrode 235 and a top electrode 240 separated by an insulator 245. In some implementations, the capacitor is a linear dielectric capacitor, and the insulator 245 is a linear dielectric insulator that comprises, consists of, or consists essentially of linear dielectric material. Alternatively, the capacitor may be a paraelectric capacitor, and the insulator 245 may be a paraelectric insulator that comprises, consists of, or consists essentially of paraelectric material. Alternatively, the capacitor may be a ferroelectric capacitor, and the insulator 245 may be a ferroelectric insulator that comprises, consists of, or consists essentially of ferroelectric material. When the access line 215 is activated (e.g., when a voltage is applied to the access line 215), the gate 230 coupled to the access line 215 may be activated. When the gate 230 is activated, the transistor 205 couples the digit line 220 to the bottom electrode 235 of the capacitor 210. A state of the memory cell 200 may then be written or read via the digit line 220.

The top electrode 240 of the capacitor 210 may be coupled to the plate line 225 and a cell plate 250. To write to (or program) the memory cell 200, the access line 215 may be activated, and a voltage may be applied across the capacitor 210 by controlling the voltage of the top electrode 240 (via the plate line 225 and/or the cell plate 250) and/or the bottom electrode 235 (via the digit line 220).

For a linear dielectric capacitor or a paraelectric capacitor, the cell plate 250 may grounded, and the capacitor 210 may be charged by applying a voltage to the bottom electrode 235 via the digit line 220. Alternatively, for a ferroelectric capacitor, the applied voltage creates an electric field, and the atoms in the ferroelectric material of the insulator 245 respond to the electric field to become arranged in a particular state (e.g., a particular orientation or polarization), which is representative of a data state (e.g., a logic “0” state or a logic “1” state). In some implementations, data may be stored using the capacitor 210 by controlling a voltage difference and/or a polarity difference of the capacitor 210 (e.g., of the insulator 245 between the bottom electrode 235 and the top electrode 240). For example, a voltage of the cell plate 250 and the digit line 220 may be controlled. In some implementations, a negative polarity of the insulator 245 as compared to the cell plate 250 results in a logic “0” state being stored in the capacitor 210, and a positive polarity of the insulator 245 as compared to the cell plate 250 results in a logic “1” state being stored in the capacitor 210.

To read the memory cell 200 (e.g., a state stored by the capacitor 210), the access line 215 may be activated, and a voltage may be applied to the plate line 225. Applying a voltage to the plate line 225 may cause a change in the stored charge on the capacitor 210. The magnitude of the change in stored charge may depend on the stored state of capacitor 210 (e.g., whether the stored state is a logic “1” state or a logic “0” state). This may or may not induce a threshold change in the voltage of the digit line 220 based on the charge stored on the capacitor 210. The change in voltage or lack of change in voltage of the digit line 220 (or a magnitude of the change in voltage) may be used to determine the stored state of the capacitor 210. For example, if the change in voltage satisfies a threshold, then the read operation indicates that a first state was stored in the capacitor 210, whereas if the change in voltage does not satisfy the threshold, then the read operation determines that a second state was stored in the capacitor 210. In some cases, multiple threshold voltages may be used, such as when the capacitor is capable of storing more than two data states (e.g., for a multi-level cell, a triple-level cell, and so on).

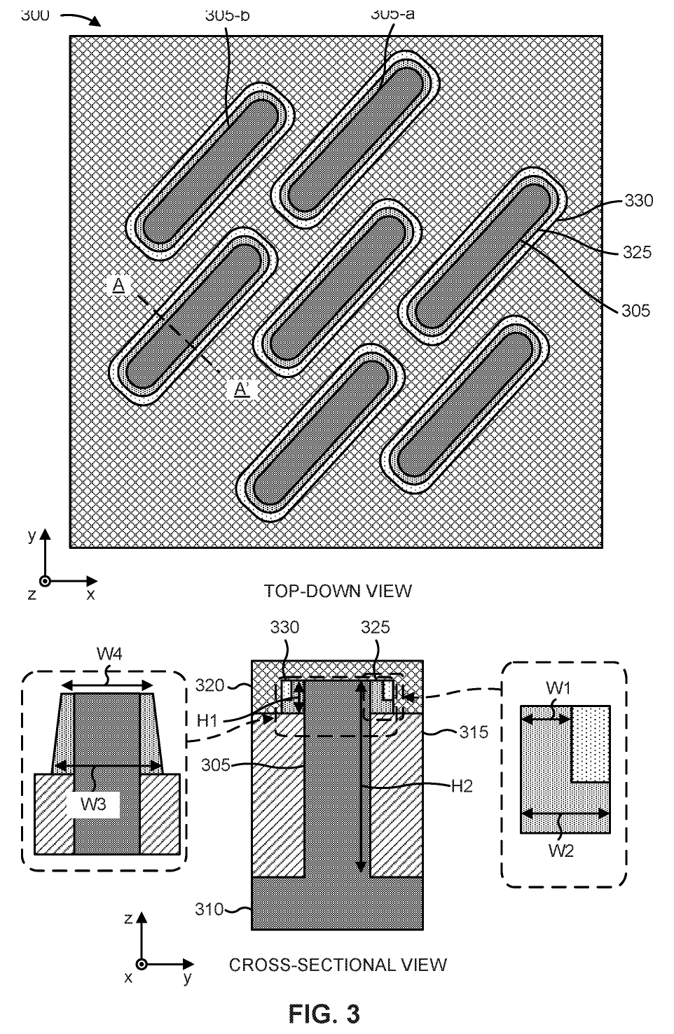

In some implementations, the transistor 205 may include a cell contact 255, a digit line contact 260 (sometimes referred to as a bit line contact or a bit contact), and one or more semiconductor pillars extending vertically from a semiconductor substrate. The cell contact 255 may be part of a connection between the transistor 205 and the capacitor 210. For example, the cell contact 255 may include doped semiconductor material (e.g., n-type doped semiconductor material or p-type doped semiconductor material) coupled with a first semiconductor pillar of the one or more semiconductor pillars, and may form a first terminal of the transistor 205. The digit line contact 260 may be part of a connection between the transistor 205 and the digit line 220. For example, the cell contact 255 may include doped semiconductor material (e.g., n-type doped semiconductor material or p-type doped semiconductor material) coupled with a second semiconductor pillar of the one or more semiconductor pillars, and may form a second terminal of the transistor 205. Thus, the cell contact 255 may be used as the source terminal of the transistor 205, the digit line contact 260 may be used as the drain terminal of the transistor 205, and the one or more semiconductor pillars may be used as a channel region of the transistor 205. As described in greater detail in connection with FIGS. 3 through 5K, the one or more semiconductor pillars may include respective overhangs extending horizontally (e.g., in a direction parallel to the substrate). An overhang may increase the active area of a semiconductor pillar, which may allow for more robust and reliable connections between the semiconductor pillar and contacts, such as a cell contact 255 and/or a digit line contact 260.

As indicated above, FIG. 2 is provided as an example. Other examples may differ from what is described with respect to FIG. 2.

FIG. 3 is a diagrammatic view of an example structure 300. The structure 300 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller). FIG. 3 illustrates a top view and a cross-sectional view (e.g., a cross-section defined by a plane A-A’) of the structure 300.

As shown in FIG. 3, the structure 300 may include an array of one or more semiconductor pillars 305. A semiconductor pillar 305 (e.g., each semiconductor pillar 305) may extend vertically (e.g., in the z-direction) from a substrate 310. The structure 300 may further include one or more dielectric materials extending between the array of semiconductor pillars 305. For example, the structure 300 may include a dielectric material 315 above the substrate 310 and a dielectric material 320 above the dielectric material 315. The dielectric materials 315 and 320 may be insulative materials used to isolate adjacent semiconductor pillars 305 and/or provide mechanical support to the structure 300 during manufacturing operations. In some examples, the dielectric material 315 may be an oxide material, such as silicon dioxide, aluminum oxide, hafnium oxide, and/or titanium dioxide, among other examples, and the dielectric material 320 may be a nitride material, such as silicon nitride. A semiconductor pillar 305 may be a semiconductor material, such as epitaxially grown silicon and/or polycrystalline silicon.

The semiconductor pillars 305 may be configured to connect to respective cell contacts 255 and/or digit line contacts 260 of memory cells 200 of a memory device as part of forming one or more transistors 205. For example, the semiconductor pillars 305 may be as part of a channel of a transistor 205, and respective upper surfaces of the semiconductor pillars 305 may be configured as active areas of the transistor 205. An active area may be a portion of a semiconductor pillar 305 configured to couple the semiconductor pillar 305 with one or more components of the memory device. Said another way, an active area may be an interface between a semiconductor pillar 305 and a component of the memory device (e.g., the active area may be in physical contact with the component of the memory device). For example, an active area of a semiconductor pillar 305-a may be an interface between the semiconductor pillar 305-a with a cell contact 255 of a memory cell 200. Additionally, an active area of a semiconductor pillar 305-b may an interface between the semiconductor pillar 305-b and a digit line contact 260. Accordingly, for the array of semiconductor pillars 305, upper surfaces (e.g., active areas) of a first subset of the semiconductor pillars 305 may be configured to be coupled to respective cell contacts 255 of an array of memory cells 200. Additionally, upper surfaces of a second subset of the semiconductor pillars 305 may be configured to be coupled to respective digit line contacts 260 of the array of memory cells 200.

A semiconductor pillar 305 may include one or more overhangs 325 extending from respective upper sidewalls of the semiconductor pillar 305. An overhang 325 may extend around the outer perimeter of a semiconductor pillar 305, as illustrated in the top-down view of the structure 300. For example, the overhang 325 may extend over at least a portion of the dielectric material 315. The overhang 325 may be a semiconductor material (e.g., polycrystalline silicon). Accordingly, the overhang 325 may extend the active area of a semiconductor pillar 305, for example by effectively increasing the area of the upper surface of the semiconductor pillar 305. Said another way, an upper width of a semiconductor pillar 305 (e.g., in a horizontal direction parallel to the plane A-A’) may be greater than a lower width of the semiconductor pillar 305. By increasing the active area of a semiconductor pillar 305, the performance and/or reliability of a memory device that includes the semiconductor pillar 305 may be enhanced. For example, an increased active area may allow for more robust and reliable connections between the semiconductor pillars 305 and contacts, such as cell contacts 255 and/or digit line contacts 260.

The height H1 (e.g., in the z-direction) of an overhang 325 may be significantly less than the height H2 of a semiconductor pillar 305. For example, the height H1 of an overhang 325 may be between approximately 15 and 35 nanometers (nm), while the height H2 of a semiconductor pillar 305 may be approximately 215 nm. The height of the overhang 325 being less than the entire height of the semiconductor pilar 305 reduces the likelihood of manufacturing defects, such as toppling and/or clogging, that might otherwise occur if the lateral size of the active area were expanded along the full height of the semiconductor pillar 305. In some implementations, the height of an overhang 325 may be between one-tenth (1/10) and one-fifth (1/5) the height of the semiconductor pillar 305, which may reduce the likelihood of manufacturing defects.

In some examples, the width W1 (e.g., in the y-direction) of an upper portion of an overhang 325 may be greater than the width W2 of a lower portion of the overhang 325. For example, as illustrated in FIG. 3, the overhang 325 may include a first rectangular portion having the width W1 the width W1 (e.g., in the y-direction) and a first height (e.g., in the z-direction). A sidewall of the first rectangular portion may be abutting the upper sidewall portion of the semiconductor pillar 305. The overhang 325 may further include a second rectangular portion having the width W2 and a second height. A lower surface of the second rectangular portion may be abutting an upper surface of the dialectic material 315. The width W2 may be greater than the width W1, and the second height may be less than the first height.

Alternatively, an overhang 325 may taper along the z-direction, resulting in a tapered profile of a semiconductor pillar 305. For example, the width of the semiconductor pillar 305 and the associated overhangs 325 may taper from a width W3 (e.g., approximately 13 nm) at a lower region (at the interface of the overhangs 325 and the dielectric material 315) to a width W4 (e.g., approximately 10 nm) at the upper portion of the semiconductor pillar 305.

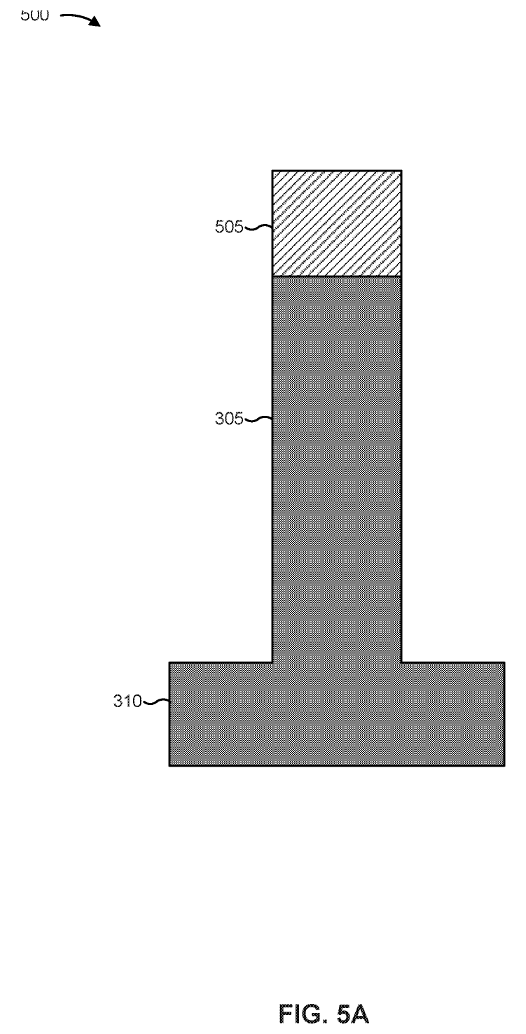

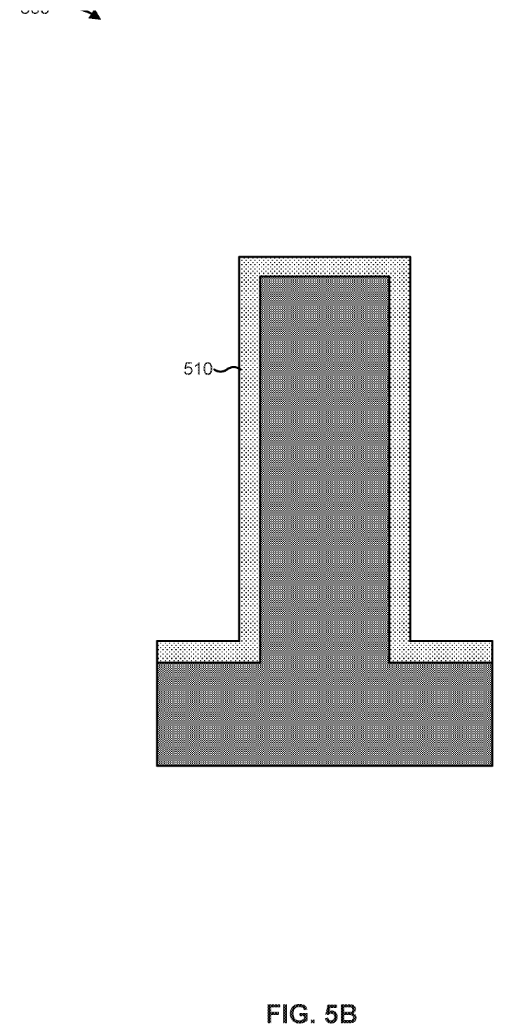

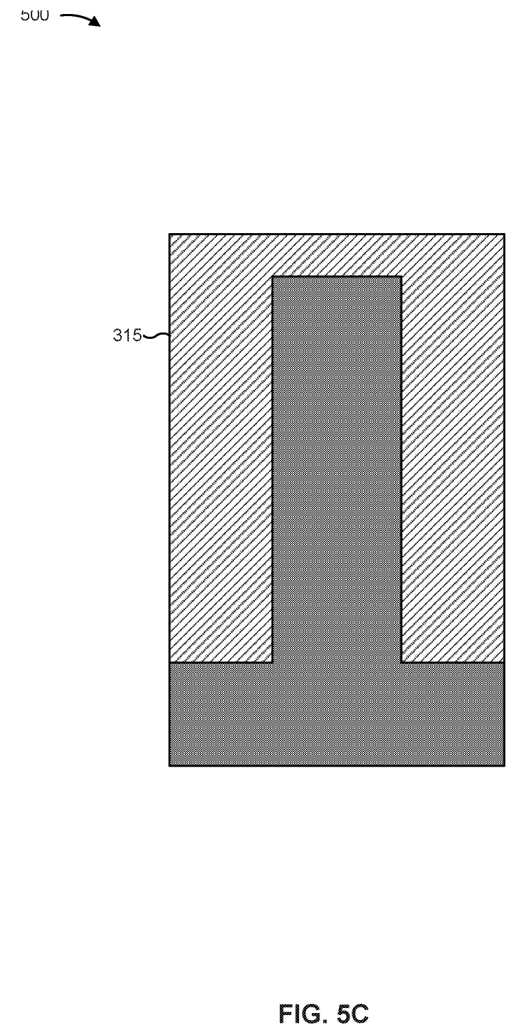

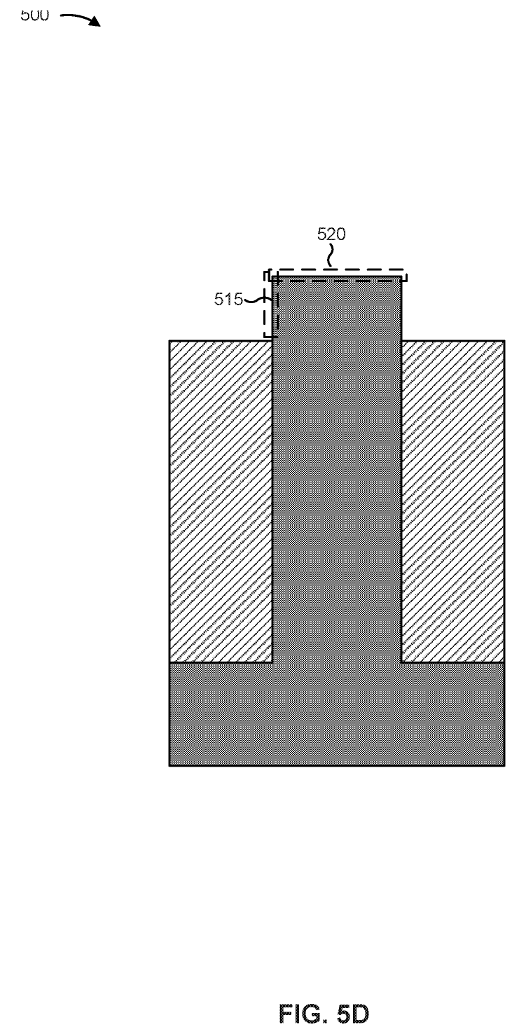

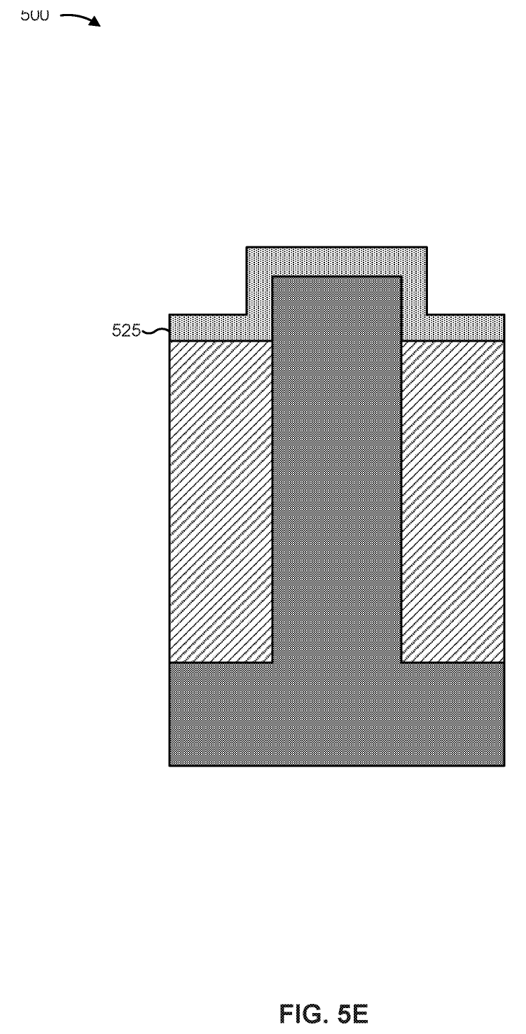

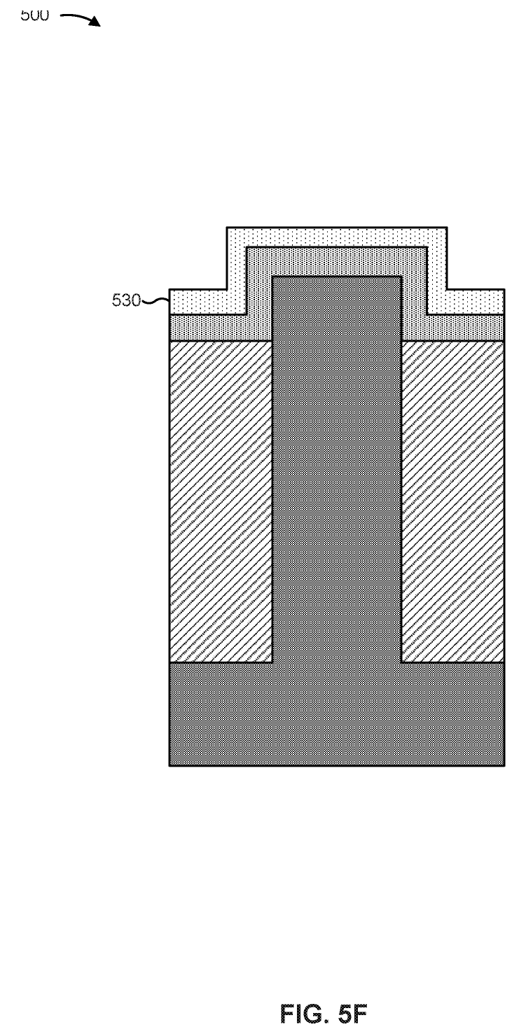

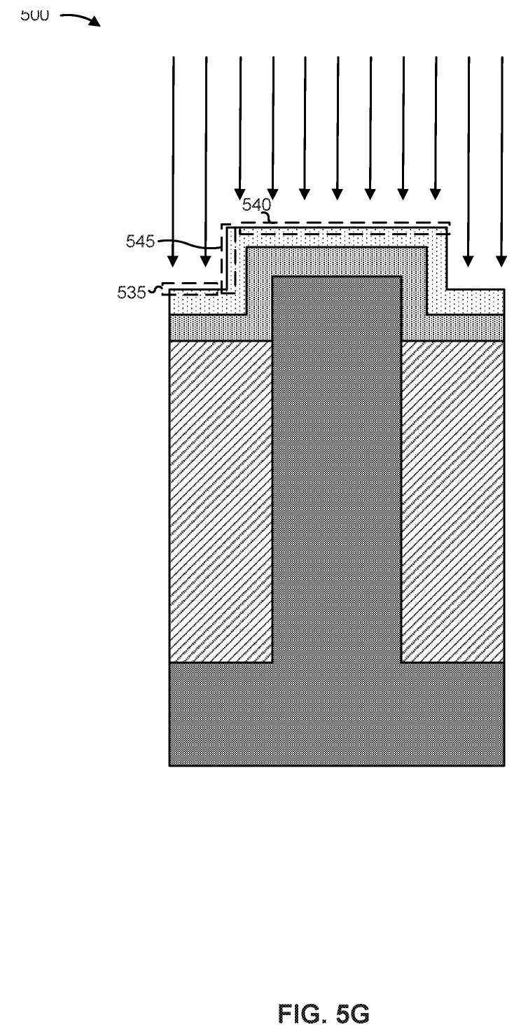

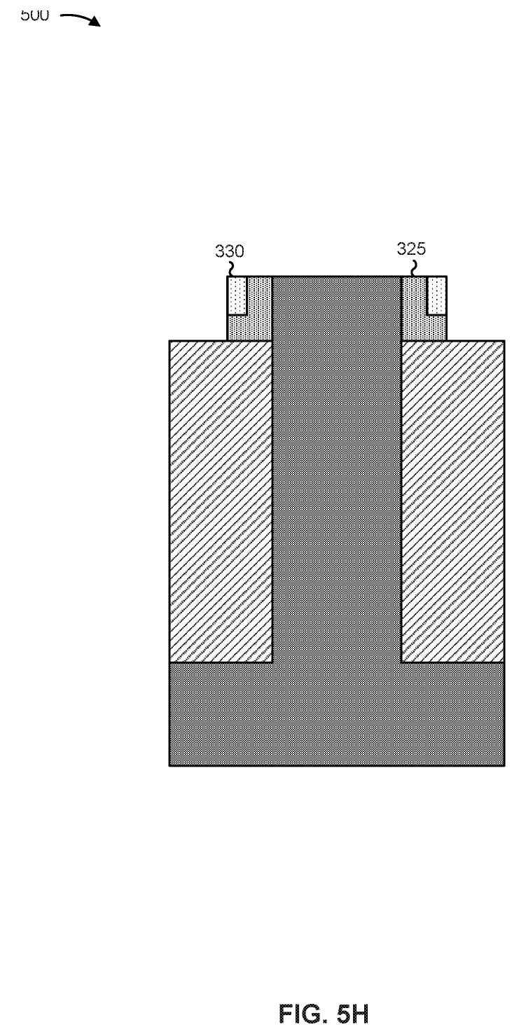

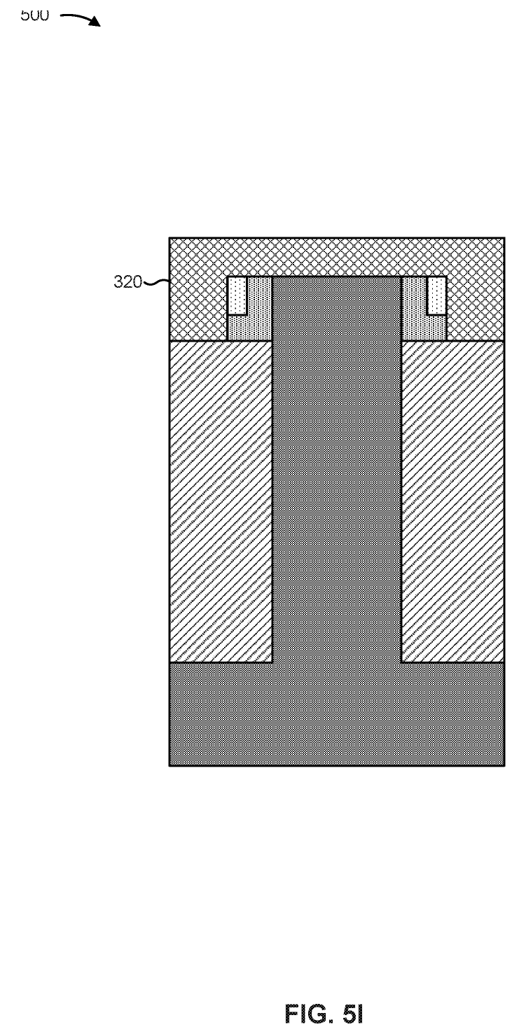

In some examples, the structure 300 may include one or more protective liner structures 330 abutting sidewalls of the respective overhangs 325. The protective line structures 330 may include a dielectric material, such as silicon oxycarbide and/or silicon nitride. As described in greater detail in connection to FIGS. 5F through 5I, the one or more protective liner structures 330 may support manufacturing operations to remove portions of a semiconductor liner material to form the overhangs 325. For example, a protective liner structure 330 may abut sidewalls of an overhang 325 and/or a semiconductor pillar 305. A protective liner structure 330 may have an approximately rectangular shape. Alternatively, as described in greater detail in connection to FIGS. 5J through 5K, a manufacturing process for the structure 300 may omit forming the protective liner structures 330. In such cases, the cross-sectional shape of an overhang may be approximately rectangular. For example, the width (e.g., in the y-direction) of an upper portion of an overhang 325 may be approximately equal to the width of a lower portion of the overhang 325.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As indicated above, FIG. 3 is provided as an example. Other examples may differ from what is described with regard to FIG. 3.

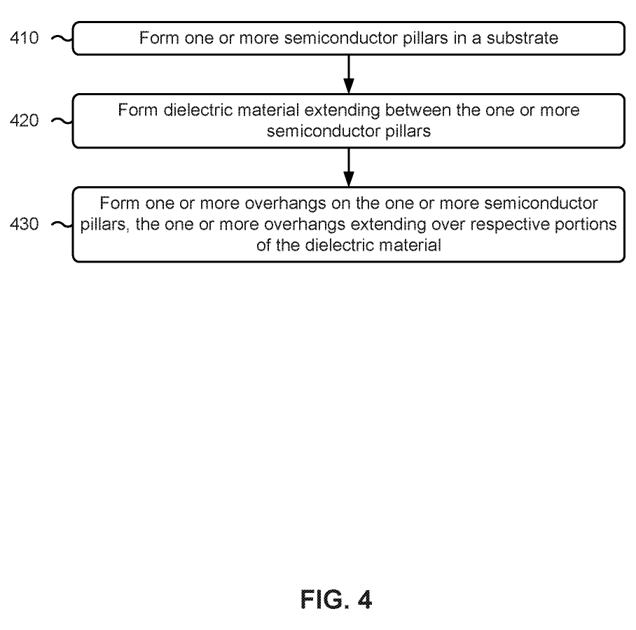

FIG. 4 is a flowchart of an example method 400 of forming an integrated assembly or memory device having an increased active area for semiconductor pillars. In some implementations, one or more process blocks of FIG. 4 may be performed by various semiconductor manufacturing equipment.

As shown in FIG. 4, the method 400 may include forming one or more semiconductor pillars in a substrate (block 410). As further shown in FIG. 4, the method 400 may include forming dielectric material extending between the one or more semiconductor pillars (block 420). As further shown in FIG. 4, the method 400 may include forming one or more overhangs on the one or more semiconductor pillars, the one or more overhangs extending over respective portions of the dielectric material (block 430).

The method 400 may include additional aspects, such as any single aspect or any combination of aspects described below and/or in connection with one or more other methods described elsewhere herein.

In a first aspect, forming the one or more semiconductor pillars comprises forming one or more trenches in the substrate based on removing one or more portions of the substrate, wherein the one or more trenches expose respective sidewalls of the one or more semiconductor pillars.

In a second aspect, alone or in combination with the first aspect, the method 400 includes forming semiconductor liner material over the one or more semiconductor pillars, wherein forming the dielectric material removes a portion of the semiconductor liner material.

In a third aspect, alone or in combination with one or more of the first and second aspects, the method 400 includes removing a portion of the dielectric material to expose respective sidewall portions of the one or more semiconductor pillars, wherein the one or more overhangs are formed on the respective sidewall portions.

In a fourth aspect, alone or in combination with one or more of the first through third aspects, forming the one or more overhangs comprises forming semiconductor liner material to cover the respective sidewall portions of the one or more semiconductor pillars, and removing one or more portions of the semiconductor liner material.

In a fifth aspect, alone or in combination with one or more of the first through fourth aspects, removing the one or more portions of the semiconductor liner material comprises forming liner material to cover the semiconductor liner material, and performing a chemical etching procedure to remove one or more portions of the liner material and to remove the one or more portions of the semiconductor liner material.

In a sixth aspect, alone or in combination with one or more of the first through fifth aspects, removing the one or more portions of the semiconductor liner material comprises performing a dry etching procedure to remove the one or more portions of the semiconductor liner material.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the structure 300, an integrated assembly that includes the structure 300, any part described herein of the structure 300, and/or any part described herein of an integrated assembly that includes the structure 300. For example, the method 400 may include forming one or more of the semiconductor pillars 305 and/or the overhangs 325.

FIGS. 5A through 5I are diagrammatic views showing formation of the structure 300 at example process stages of an example process 500 of forming the structure 300. In some implementations, the example process described below in connection with FIGS. 5A through 5I may correspond to the method 400 and/or one or more blocks of the method 400. However, the process described below is an example, and other example processes may be used to form the structure 300, an integrated assembly that includes the structure 300, and/or one or more parts of the structure 300 and/or the integrated assembly.

As shown in FIG. 5A, the process 500 may include forming the one or more semiconductor pillars 305 on the substrate 310. In some cases, the one or more semiconductor pillars 305 may be formed using shallow trench isolation (STI) techniques (e.g., the one or more semiconductor pillars 305 may be STI pillars). For example, the process 500 may include removing (e.g., etching) one or more portions of the substrate 310 to form one or more trenches. A trench may expose one or more sidewalls of a semiconductor pillar 305. Said another way, the one or more trenches may define the one or more semiconductor pillars 305.

Forming the one or more trenches may include forming a masking material 505, such as a hard mask oxide material, over portions of the substrate 310. A photoresist material may be deposited (e.g., spin-coated) onto the masking material 505 and exposed to radiation to form a pattern in the photoresist material. A developer may be used to remove portions to reveal the pattern, and the masking material 505 may be etched to transfer the pattern to the masking material 505. The pattern in the masking material 505 may then be used to etch the substrate 310 and define the semiconductor pillars 305, for example using a plasma-based etch. In some examples, after forming the one or more trenches, the masking material 505 may be removed, for example using a wet etchant selective to the masking material 505.

As shown in FIG. 5B, the process 500 may include forming (e.g., depositing and/or growing) a semiconductor liner material 510 over the one or more semiconductor pillars 305, such as by using a chemical vapor deposition (CVD) process. The semiconductor liner material 510 may comprise, consist of, or consist essentially of silicon (e.g., polycrystalline silicon), among other examples. In some examples, all or a portion of the semiconductor liner material 510 may be consumed as part of subsequent processing steps.

For example, as shown in FIG. 5C, the process 500 may include forming a dielectric material 315 extending between the one or more semiconductor pillars 305. The dielectric material 315 may comprise, consist of, or consist essentially of an oxide material. In some implementations, forming the dielectric material 315 may consume all or a portion of the semiconductor liner material 510. For example, the dielectric material 315 may oxidize exposed portions of the semiconductor liner material 510. Oxidized portions of the semiconductor liner material may thus be converted to a portion of the dielectric material 315.

As shown in FIG. 5D, the process 500 may include removing (e.g., etching) one or more portions of the dielectric material 315 to expose one or more upper sidewall portions 515 of the semiconductor pillar 305 and/or an upper surface 520 of the semiconductor pillar 305. Removing the one or more portions of the dielectric material may expose approximately 25 to 35 nm of the semiconductor pillar 305 (e.g., the one or more upper sidewall portions 515 of the semiconductor pillar 305 may have a height, in the z-direction, of approximately 25 to 35 nm). In some cases, removing the one or more portions of the dielectric material 315 may include a vapor etch, such as an oxygen vapor etch. In some implementations, one or more masks may be used to expose the one or more upper sidewall portions 515 and/or the upper surface 520. For example, one or more masks may be deposited and/or patterned on the dielectric material 315 prior to removing the one or more portions of the dielectric material 315.

As shown in FIG. 5E, the process 500 may include forming (e.g., depositing and/or growing) a semiconductor liner material 525 (e.g., using a CVD process) to cover the upper sidewall portions 515 of the semiconductor pillar 305 and the upper surface 520 of the semiconductor pillar 305. The semiconductor liner material 525 may comprise, consist of, or consist essentially of silicon (e.g., polycrystalline silicon), among other examples.

In some implementations, as shown in FIG. 5F, the process 500 may include forming a protective liner material 530 to cover the semiconductor liner material 525. The protective liner material 530 may comprise, consist of, or consist essentially of a material to be removed and/or damaged by a selective etching procedure, such as directional plasma process (e.g., an oxygen plasma process). For example, the protective liner material 530 may include a dielectric material, such as silicon oxycarbide (SiOC) and/or silicon nitride (SixNy), among other examples.

As shown in FIG. 5G, the process 500 may include performing the selective etching procedure. In some implementations, the selective etching procedure may be anisotropic. For example, the selective etching procedure may damage upper surfaces of the protective liner material 530 (e.g., an upper surface 535 and/or an upper surface 540) at a higher rate than sidewalls of the protective liner material 530 (e.g., a sidewall 545). The selective etching procedure may include extracting one or more elements from the protective liner material 530. For example, if the protective liner material 530 includes SiOC, the selective etching procedure may extract carbon from the protective liner material 530, leaving silicon oxide. In some examples, the selective etching procedure may damage the semiconductor liner material 525 beneath the protective liner material 530 (e.g., beneath the upper surfaces 535 and/or 540), such as by converting a portion of the semiconductor liner material to silicon oxide.

As shown in FIG. 5H, the process 500 may include removing the one or more portions of the semiconductor liner material 525 and removing the one or more portions of the protective liner material 530, such as by using a chemical etching procedure (e.g., a wet etch) to form the one or more overhangs 325. The chemical etching procedure may remove damaged portions of the protective liner material 530 at a higher rate than undamaged portions of the protective liner material 530. Accordingly, the chemical etching procedure may substantially remove the upper surfaces 535 and 540, while leaving the sidewalls 545 substantially intact, which may form the one or more liner structures 330. The chemical etching procedure may further remove portions of the semiconductor liner material 525 exposed by the removal of the upper surfaces 535 and 540, which may isolate the semiconductor pillar 305 from adjacent semiconductor pillars 305. Further, the chemical etching procedure may retain portions of the semiconductor liner material 525 covered by the sidewalls 545 to form the one or more overhangs 325, which may increase the effective active area of the semiconductor pillar 305.

As shown in FIG. 5I, the process 500 may include forming (e.g., depositing) the dielectric material 320 over the semiconductor pillar 305, the overhangs 325, and/or the liner structures 330.

As indicated above, the process steps described in connection with FIGS. 5A through 5I are provided as examples. Other examples may differ from what is described with respect to FIGS. 5A through 5I. The structure shown in FIGS. 5I may be equivalent to the structure 300 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

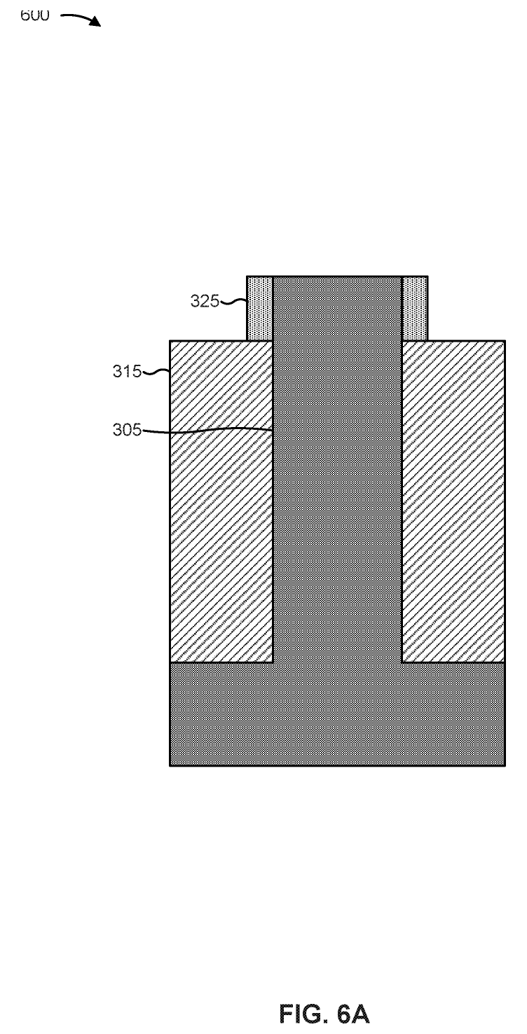

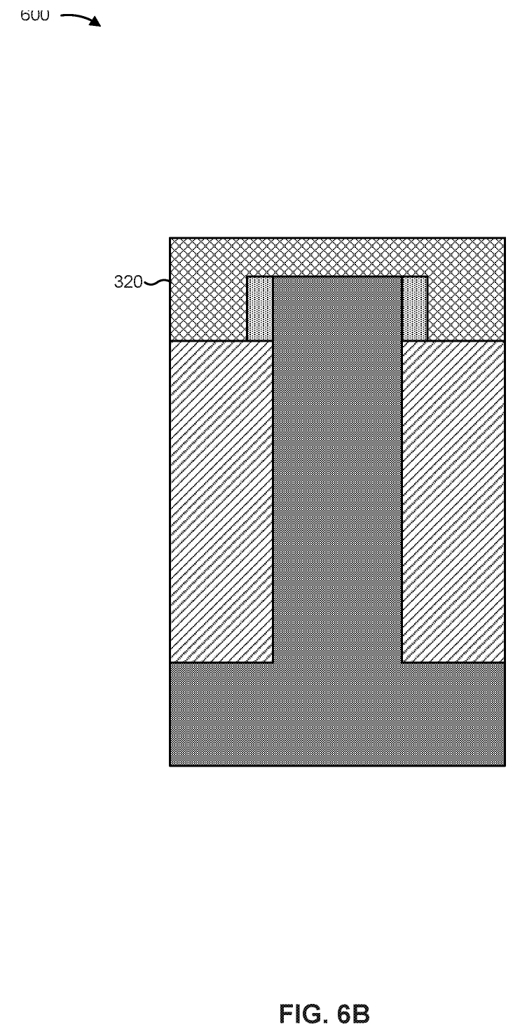

FIGS. 6A and 6B are diagrammatic views showing formation of the structure 300 at example process stages of an example process 600 of forming the structure 300. For example, FIGS. 6A and 6B may illustrate processing steps following the processing steps described in connection with FIG. 5E. In some implementations, the example process described below in connection with FIGS. 6A and 6B may correspond to the method 400 and/or one or more blocks of the method 400. However, the process described below is an example, and other example processes may be used to form the structure 300, an integrated assembly that includes the structure 300, and/or one or more parts of the structure 300 and/or the integrated assembly.

As shown in FIG. 6A, the process 600 may include the removing one or more portions of the semiconductor liner material 525 to form one or more overhangs 325 using a dry etching procedure, such as a plasma-based etch. In such examples, the process 600 may omit forming a protective liner material (e.g., may omit forming the protective liner material 530). The dry etching procedure may be anisotropic. For example, the dry etching procedure may remove portions of the semiconductor liner material 525 arranged on upper surfaces of the dielectric material 315 and/or the semiconductor pillar 305, which may isolate the semiconductor pillar 305 from adjacent semiconductor pillars 305. Further, the dry etching procedure may leave portions of the semiconductor liner material 525 arranged on the upper sidewall portions 515 of the semiconductor pillar 305 intact to form the one or more overhangs 325, which may increase the effective active area of the semiconductor pillar 305.

As shown in FIG. 6B, the process 600 may include forming (e.g., depositing) the dielectric material 320 over the semiconductor pillar 305 and/or the overhangs 325.

As indicated above, the process steps described in connection with FIGS. 6A and 6B are provided as examples. Other examples may differ from what is described with respect to Figs. FIGS. 6A and 6B. The structure shown in FIGS. 6B may be equivalent to the structure 300 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

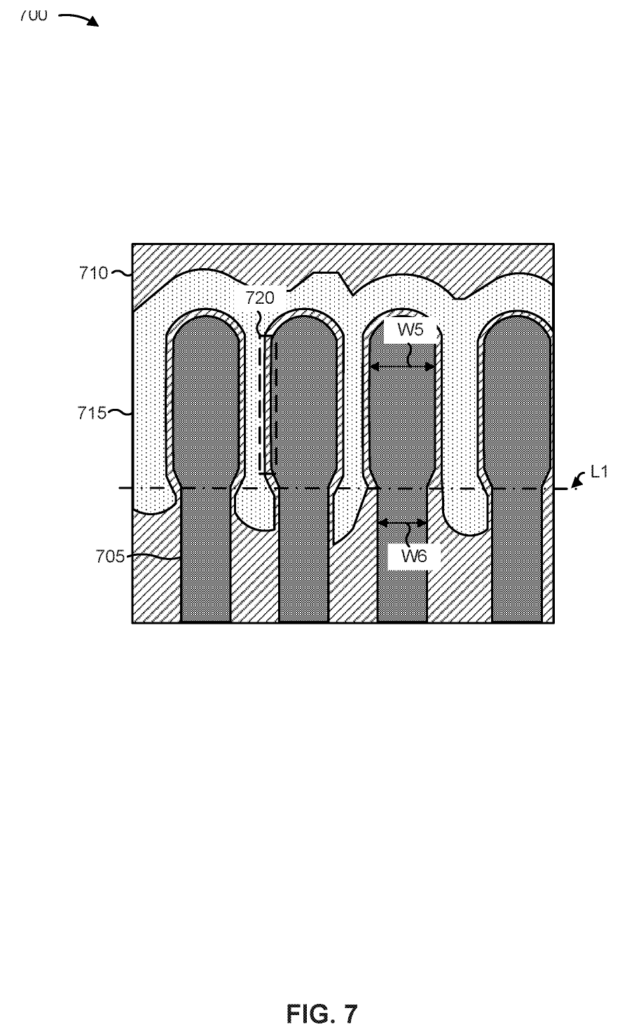

FIG. 7 is a diagrammatic view of an example structure 700. The structure 700 may represent a measured image, such as a transmission electron microscopy (TEM) image, of the structure 300. For example, the TEM image may be obtained by measuring the presence of various materials, such as semiconductor material 705, oxide material 710, and/or conductive material 715 within the structure 300.

The semiconductor material 705 may correspond to the one or more semiconductor pillars 305 and/or the one or more overhangs 325. As shown in Fig.7, the semiconductor material 705 may have a rounded upper profile. For example, upper corners of the semiconductor pillar(s) 305 and/or the overhang(s) 325 may curve outwardly (e.g., may be beveled). Additionally, upper surfaces of the semiconductor pillar(s) 305 and/or the overhang(s) 325 may be curve outwardly away from the substrate 310.

The width W5 of a semiconductor pillar above the line L1 (e.g., above the oxide material 315) may be greater than the width W6 below the line L1. The increased width may be due to the presence of the overhang(s) 325. For example, the width W5 may be between approximately 10 nm and 13 nm, while the width W6 may be between approximately 7 nm and 8 nm. Accordingly, the overhang(s) 325 associated with a semiconductor pillar 305 may expand the active area of the semiconductor pillar 305.

The oxide material 710 may include the oxide material 315 and/or the protective liner material 330. As shown in FIG. 7, the oxide material 710 may be present between the semiconductor material 705 and the conductive material 715. For example, the structure 700 may include one or more sidewall regions 720 (e.g., sidewall regions of semiconductor pillars 305) having a significant proportion of oxide material 710. Said another way, the concentration of oxide material 710 within a sidewall region 720 may be greater than the presence of semiconductor material 705 and/or conductive material 715 within the sidewall region 720.

The presence of the oxide material 710 within the sidewall region(s) 720 may result from the inclusion of the protective liner structures 330. For example, a sidewall region 720 may correspond to the position of a protective liner structure 330. Because the protective liner structure 330 may include oxygen (e.g., if the protective liner structure 330 includes silicon oxycarbide), integrated assemblies that include protective liner structures 330 may have an increased concentration of oxygen within sidewall region(s) 720 relative to integrated assemblies that do not include the protective liner structures 330.

As indicated above, FIG. 7 is provided as an example. Other examples may differ from what is described with respect to FIG. 7.

In some implementations, an integrated assembly includes one or more semiconductor pillars extending vertically from a substrate, the one or more semiconductor pillars comprising respective upper portions having a first width in a horizontal direction and the one or more semiconductor pillars comprising respective lower portions having a second width in the horizontal direction, wherein the first width is greater than the second width; and a first dielectric material extending between the one or more semiconductor pillars, wherein the respective upper portions extend over respective portions of the first dielectric material.

In some implementations, an integrated assembly includes a substrate; an array of semiconductor pillars extending vertically from the substrate, the one or more semiconductor pillars comprising respective overhangs extending in a horizontal direction; and a first dielectric material extending between the one or more semiconductor pillars, wherein the respective overhangs extend over respective portions of the first dielectric material.

In some implementations, a method includes forming one or more semiconductor pillars in a substrate; forming dielectric material extending between the one or more semiconductor pillars; and forming one or more overhangs on the one or more semiconductor pillars, the one or more overhangs extending over respective portions of the dielectric material.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise. As used herein, the term “formed” may, depending on the context, refer to a state or a position of a first feature relative to a second feature, and does not imply any specific method or sequence of formation.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
one or more semiconductor pillars extending vertically from a substrate, the one or more semiconductor pillars comprising respective upper portions having a first width in a horizontal direction and the one or more semiconductor pillars comprising respective lower portions having a second width in the horizontal direction, wherein the first width is greater than the second width; and
a first dielectric material extending between the one or more semiconductor pillars, wherein the respective upper portions extend over respective portions of the first dielectric material.

2. The integrated assembly of claim 1, further comprising:
one or more liner structures on respective sidewalls of the respective upper portions of the one or more semiconductor pillars.

3. The integrated assembly of claim 2, wherein the one or more liner structures comprise silicon oxide carbon material.

4. The integrated assembly of claim 1, further comprising:
a second dielectric material extending between the respective upper portions of the one or more semiconductor pillars.

5. The integrated assembly of claim 4, wherein the first dielectric material comprises oxide and the second dielectric material comprises nitride.

6. The integrated assembly of claim 1, wherein the one or more semiconductor pillars comprise silicon.

7. The integrated assembly of claim 1, further comprising:
one or more cell contacts configured to be coupled with respective first semiconductor pillars of a first subset of the one or more semiconductor pillars; and
one or more digit line contacts configured to be coupled with respective second semiconductor pillars of a second subset of the one or more semiconductor pillars.

8. An integrated assembly, comprising:
a substrate;
an array of semiconductor pillars extending vertically from the substrate, the one or more semiconductor pillars comprising respective overhangs extending in a horizontal direction; and
a first dielectric material extending between the one or more semiconductor pillars, wherein the respective overhangs extend over respective portions of the first dielectric material.

9. The integrated assembly of claim 8, further comprising:
one or more liner structures extending from respective sidewalls of the respective overhangs of the one or more semiconductor pillars.

10. The integrated assembly of claim 9, wherein the one or more liner structures comprise silicon oxide carbon material.

11. The integrated assembly of claim 8, wherein respective first upper surfaces of a first subset of the one or more semiconductor pillars are configured to be coupled to respective cell contacts and respective second upper surfaces of a second subset of the one or more semiconductor pillars are configured to be coupled to respective digit line contacts.

12. The integrated assembly of claim 8, wherein respective upper surfaces of the one or more semiconductor pillars are configured as active areas.

13. The integrated assembly of claim 8, further comprising:
a second dielectric material extending between the respective overhangs of the one or more semiconductor pillars.

14. A method, comprising:
forming one or more semiconductor pillars in a substrate;
forming dielectric material extending between the one or more semiconductor pillars; and
forming one or more overhangs on the one or more semiconductor pillars, the one or more overhangs extending over respective portions of the dielectric material.

15. The method of claim 14, wherein forming the one or more semiconductor pillars comprises:
forming one or more trenches in the substrate based on removing one or more portions of the substrate, wherein the one or more trenches expose respective sidewalls of the one or more semiconductor pillars.

16. The method of claim 15, further comprising:
forming semiconductor liner material over the one or more semiconductor pillars, wherein forming the dielectric material removes a portion of the semiconductor liner material.

17. The method of claim 14, further comprising:
removing a portion of the dielectric material to expose respective sidewall portions of the one or more semiconductor pillars, wherein the one or more overhangs are formed on the respective sidewall portions.

18. The method of claim 17, wherein forming the one or more overhangs comprises:
forming semiconductor liner material to cover the respective sidewall portions of the one or more semiconductor pillars; and
removing one or more portions of the semiconductor liner material.

19. The method of claim 18, wherein removing the one or more portions of the semiconductor liner material comprises:
forming liner material to cover the semiconductor liner material; and
performing a chemical etching procedure to remove one or more portions of the liner material and to remove the one or more portions of the semiconductor liner material.

20. The method of claim 18, wherein removing the one or more portions of the semiconductor liner material comprises:
performing a dry etching procedure to remove the one or more portions of the semiconductor liner material.
